(19) United States
(12) Patent Application Publication
(10) Pub. No.: US 2020/0150168 A1
(43) Pub. Date: May 14, 2020

(54) DETECTION DEVICE FOR MEASURING ANTENNA

(71) Applicants: Ting Yuan LEE, Taipei City (TW); Miao-Lin HSU, Zhubei City (TW); Tsung-Hsin LIU, Zhubei City (TW); Yi-Ting LIN, Zhubei City (TW)

(72) Inventors: Ting Yuan LEE, Taipei City (TW); Miao-Lin HSU, Zhubei City (TW); Tsung-Hsin LIU, Zhubei City (TW); Yi-Ting LIN, Zhubei City (TW)

(21) Appl. No.: 16/184,294

(22) Filed: Nov. 8, 2018

(51) Int. Cl. G01R 29/10; G01R 29/08

(52) U.S. Cl. CPC G01R 29/10; G01R 29/0878

(57) ABSTRACT

A detection device for measuring an antenna is disclosed, wherein it is provided with a probe seat made of a metal material; a front end of the probe seat is provided with an extending front arm for connecting to a probe; and a rear end of the probe seat is provided with a connector, of which one end is for connecting to a detection instrument and the other end is electrically connected to the probe through the front arm; the detection device is characterized in that an outer surface of the probe seat is covered by a wave absorbent material capable of absorbing reflected waves, thereby when measuring an antenna, the probe seat can absorb reflected waves from the antenna to measure the quality of the antenna pattern.

### BACKGROUND OF THE INVENTION

### Field of the Invention

The present invention relates to a detection device for measuring an antenna. The detection device is capable of reducing the influence of reflected waves and thus effectively determining the quality of the antenna pattern when measuring the antenna.

### Description of the Related Art

Communication products are ever-increasingly popular since their initial launches, and prospects of development thereof are also persistently optimistic. Thus, people demand more diversified communication systems, such that all aspects including wireless communications, wired communications and optoelectronics continue to thrive. Among the above, communication integrated circuits are a research and development focus of the related fields, and particularly rapidly develop towards high-frequency communications, with immense development resources invested in designing related circuits, processes and devices. However, these related development and designs all need high-frequency measurement. Using high-frequency measuring technologies, whether high-frequency devices, circuit components and system in a communication system that are decisive on whether such development is successful are functional can be verified, so as to further discover and improve possible issues.

With the miniaturization of products, the measurement for an antenna also needs to be miniaturized such that a probe is needed for the measurement. However, when a high-frequency check signal is transmitted to a probe, interference caused by reflected waves needs to be minimized in order to identify the antenna pattern and to further determine the quality of the antenna pattern.

### SUMMARY OF THE INVENTION

However, in regard to the influence affecting the quality of an antenna, the industry lacks a solution for effectively avoiding reflected waves. Therefore, to provide a structure different from the prior art, the Inventor provides the present invention on the basis of years of experience and persistent development and improvement.

It is a primary object of the present invention to provide a detection device for measuring an antenna, wherein the detection device is capable of reducing the influence of reflected waves and thus effectively determining the quality of an antenna pattern when measuring the antenna.

To achieve the above object, a detection device for a measuring antenna provided by the present invention includes a probe seat made of a metal material. A front end of the probe seat is provided with an extending front arm, onto which a probe is combined. A rear end of the probe set is provided with a connector, of which one end is for connecting to a detection instrument and the other end is electrically connected to the probe through the front arm. The detection device is characterized in that an outer surface of the probe seat is covered by a wave absorbing material capable of absorbing reflected waves, thereby when measuring an antenna, the probe seat can absorb reflected waves from the antenna to measure the quality of the antenna pattern.

In implementation, the wave absorbent material capable of absorbing reflected waves may be a wave absorbent material having certain rigidity, such as wood, foam sponge, acrylic, a pearl plate or polystyrene, so as to be combined on the outer surface of the probe seat.

In implementation, the wave absorbent material capable of absorbing reflected waves may be a coating layer, so as to be combined on the outer surface of the probe seat. The coating layer is paint or glue.

In implementation, the front arm is covered by the wave absorbent material capable of absorbing reflected waves.

To further understand the present invention, preferred embodiments are given with the accompanying drawings and denotations in the drawings below to describe substantial contents and expected results of the present invention.

### BRIEF DESCRIPTION OF THE DRAWINGS

FIG. 1 is a schematic diagram of a state of measuring an antenna according to an embodiment of the present invention; and

FIG. 2 is a structural schematic diagram of a probe seat according to an embodiment of the present invention.

### DETAILED DESCRIPTION OF THE INVENTION

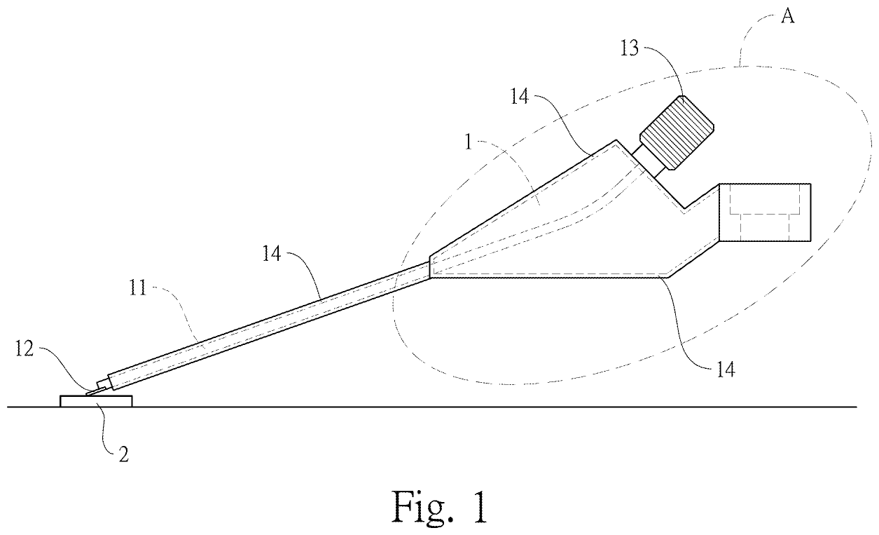

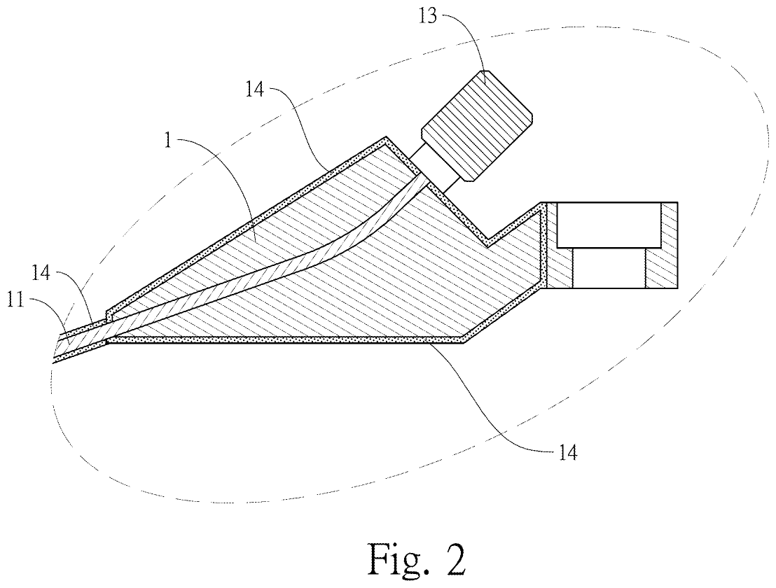

FIG. 1 and FIG. 2 show a detection device for measuring an antenna according to an embodiment of the present invention.

The detection device for measuring an antenna includes a probe seat 1 made of a metal material. A front end of the probe seat 1 is provided with an extending front arm 11, which is a copper tube for a probe 12 to be combined thereon. A rear end of the probe seat 1 is provided with a connector, of which one end is for connecting to a detection instrument (e.g., a network analyzer) and the other end is electrically connected to the probe 12 through the front arm 11.

An outer surface of the probe seat 1 is covered by a wave absorbent material 14 capable of absorbing reflected waves. Thus, when measuring an antenna, the probe seat 1 can absorb reflected waves from the antenna to further measuring the quality of the antenna pattern.

The wave absorbent material 14 capable of absorbing reflected waves may be the wave absorbent material 14 having certain rigidity, such as wood, foam sponge, acrylic, a pearl plate or polystyrene, to be combined on the outer surface of the probe seat 1. Alternatively, the wave absorbent material 14 capable of absorbing reflected waves may be a coating layer, such as paint or glue, and may be directly applied on the outer surface of the probe seat 1.

Thus, after assembly, when an antenna 2 is measured, the wave absorbent material 14 capable of absorbing reflected waves on the probe seat 1 at the rear end of the probe 12 can absorb reflected waves from a measuring end, allowing the detection instrument (e.g., a network analyzer) to more clearly identify the antenna pattern to further determine the quality of the antenna pattern.

Further, a surface of the front arm 11 can be similarly covered by the above wave absorbing material 14, thereby further enhancing the precision for the measurement.

The above disclosure describes the embodiment of the present invention and applied technical means. Various modifications and amendments may be made on the basis of the disclosure or teaching of the application, and such are regarded as equivalent changes of the concept of the present invention and provide effects covered by the substantial spirits of the description and the drawings. Therefore, such modifications and amendments made are to be encompassed within the technical scope of the present invention.

In conclusion, on the basis of the above disclosure, the detection device for measuring an antenna provided by the present invention achieves an expected result, and provides practicability and industrial applicability. Therefore, an invention application is filed accordingly.

What is claimed is:

1. A detection device for measuring an antenna, the detection device comprising a probe seat made of a metal material, wherein a front end of the probe seat is provided with an extending front arm for connecting to a probe, and a rear end of the probe seat is provided with a connector having one end used for connecting to a detection instrument and the one other end electrically connected to the probe via the front arm; the detection device is characterized in that: an outer surface of the probe seat is covered with a wave absorbent material capable of absorbing reflected waves, such that the probe seat absorbs reflected waves from the antenna when measuring the antenna to further determine a quality of an antenna pattern.

2. The detection device for measuring an antenna according to claim 1, wherein the wave absorbent material capable of absorbing reflected waves is a wave absorbing material having certain rigidity, so as to be combined on the outer surface of the probe seat.

3. The detection device for measuring an antenna according to claim 1, wherein the wave absorbent material capable of absorbing reflected waves is one of wood, foam sponge, acrylic, a pearl plate and polystyrene.

4. The detection device for measuring an antenna according to claim 1, wherein the wave absorbent material capable of absorbing reflected waves is a coating layer combined on the outer surface of the probe seat.

5. The detection device for measuring an antenna according to claim 4, wherein the coating layer is paint or glue.

6. The detection device for measuring an antenna according to claim 1, wherein the front arm is covered by the wave absorbent material capable of absorbing reflected waves.
